(19) United States
(12) Patent Application Publication
(10) Pub. No.: US 2025/0298319 A1
(43) Pub. Date: Sep. 25, 2025

(54) PHOTORESIST PATTERNING USING PLANAR TRIM LAYER

(71) Applicant: Tokyo Electron Limited, Tokyo (JP)

(72) Inventors: Michael Murphy, Albany, NY (US); Jodi Grzeskowiak, Albany, NY (US); David Conklin, Saratoga Springs, NY (US)

(21) Appl. No.: 18/615,281

(22) Filed: Mar. 25, 2024

(51) Int. Cl. G03F 7/38; G03F 7/16; G03F 7/20; G03F 7/32; G03F 7/42

(52) U.S. Cl. CPC G03F 7/38; G03F 7/168; G03F 7/202; G03F 7/322; G03F 7/426

(57) ABSTRACT

A method includes forming a photoresist layer over a substrate. The method further includes exposing the photoresist layer to a radiation to generate a first acid in exposed regions of the photoresist layer. The method further includes forming a trim layer over the photoresist layer. The trim layer includes a second acid. The method further includes performing a bake process on the substrate having the photoresist layer and the trim layer disposed thereon. Performing the bake process includes reacting the first acid with a material of the exposed regions to form first modified regions, diffusing the second acid from the trim layer into unmodified regions of the photoresist layer, and reacting the second acid with a material of the unmodified regions to form second modified regions. The method further includes and removing the trim layer, the first modified regions, and the second modified regions.

### TECHNICAL FIELD

The present disclosure relates generally to methods for processing a substrate and, in particular embodiments, to methods for photoresist patterning using a planar trim layer.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning at nanoscale features.

### SUMMARY

In accordance with an embodiment of the present disclosure, a method includes forming a photoresist layer over a substrate. The method further includes exposing the photoresist layer to a radiation to generate a first acid in exposed regions of the photoresist layer. The method further includes forming a trim layer over the photoresist layer. The trim layer includes a second acid. The method further includes performing a bake process on the substrate having the photoresist layer and the trim layer disposed thereon. Performing the bake process includes reacting the first acid with a material of the exposed regions to form first modified regions, diffusing the second acid from the trim layer into unmodified regions of the photoresist layer, and reacting the second acid with a material of the unmodified regions to form second modified regions. The method further includes and removing the trim layer, the first modified regions, and the second modified regions.

In accordance with an embodiment of the present disclosure, a method includes depositing a photoresist layer over a substrate, disposing a reticle over the photoresist layer, and exposing the photoresist layer to a UV radiation through the reticle to generate a first acid in a first exposed region and a second exposed region of the photoresist layer. A first unmodified region of the photoresist layer is interposed between the first exposed region and the second exposed region. The method further includes depositing a trim layer over the first unmodified region, the first exposed region, and the second exposed region of the photoresist layer. The trim layer includes a second acid. The method further includes performing a bake process on the substrate having the photoresist layer and the trim layer disposed thereon. Performing the bake process includes activating the first acid in the first exposed region and the second exposed region, reacting the first acid with a material of the first exposed region and the second exposed region to form a first modified region and a second modified region, diffusing the second acid from the trim layer into the first unmodified region, and reacting the second acid with a material of the first unmodified region to form a third modified region. The method further includes performing a developing process to remove the trim layer, the first modified region, the second modified region, and the third modified region.

In accordance with an embodiment of the present disclosure, a method includes depositing a photoresist layer over a substrate, wherein the photoresist layer has a first solubility to a first developer, disposing a reticle over the photoresist layer, and exposing the photoresist layer to a UV radiation through the reticle to generate a first acid in a first exposed region and a second exposed region of the photoresist layer. A first unmodified region of the photoresist layer is interposed between the first exposed region and the second exposed region. The method further includes depositing a trim layer over the first unmodified region, the first exposed region, and the second exposed region of the photoresist layer, wherein the trim layer has a second solubility to the first developer. The second solubility is greater than the first solubility. The trim layer includes a second acid. The method further includes performing a thermal process on the substrate having the photoresist layer and the trim layer disposed thereon. Performing the thermal process includes activating the first acid in the first exposed region and the second exposed region. Performing the thermal process further includes reacting the first acid with a material of the first exposed region and the second exposed region to form a first modified region and a second modified region. The first modified region and the second modified region have a third solubility to the first developer. The third solubility is greater than the first solubility. Performing the thermal process further includes diffusing the second acid from the trim layer into the first unmodified region, and reacting the second acid with a material of the first unmodified region to form a third modified region. The third modified region has a fourth solubility to the first developer. The fourth solubility is greater than the first solubility. The method further includes soaking the substrate with the photoresist layer and the trim layer disposed thereon in the first developer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1E illustrate cross-sectional views of different stages of a method for patterning a photoresist layer in accordance with various embodiments; and

FIG. 2 illustrates a process flow diagram of a method for patterning a photoresist layer in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

The standard patterning process of a photoresist may include an initial patterning process followed by a trim process. The initial patterning process of the photoresist includes locational generation of an acid through exposure to a radiation and a subsequent deprotection of exposed regions of the photoresist through a post-exposure bake to increase a solubility to a developer. A developing process is performed to remove deprotected regions of the photoresist using the developer. Unmodified regions of the photoresist form one or more photoresist mandrels.

The trim process may be performed on the photoresist mandrels to control critical dimensions (CD) of the photoresist mandrels. The standard trim process includes forming an overcoat layer or a trim layer between and over the photoresist mandrels. The overcoat layer may comprise an acid (e.g., a free acid) or an acid generator (e.g., a photo-acid generator (PAG) or a thermal-acid generator (TAG)), which generates the acid in response to a suitable activation trigger (e.g., radiation or heat). A bake process is performed to diffuse the acid into perimeter regions of the photoresist mandrels and generate additional deprotected regions with increased solubility to the developer. A developing process is performed to remove the additional deprotected regions of the photoresist using the developer. The overcoat layer may be non-planar due a topography of the photoresist mandrels, which may cause non-uniformity in a locational acid concentration. The non-uniformity in the locational acid concentration may lead to undesired profiles of trimmed photoresist mandrels.

The patterning process of the present disclosure includes locational generation of an acid through exposure of the photoresist to a radiation followed by the formation of an overcoat layer or a trim layer over the photoresist. A post-exposure bake and a developing process to form one or more photoresist mandrels is omitted. By omitting the post-exposure bake and the developing process, efficiency of the patterning process is improved. As the overcoat layer is formed over a planar photoresist, the overcoat layer is a planar layer with a uniform thickness and a uniform locational acid concentration. By forming the planar overcoat layer, non-uniformity in the locational acid concentration may be reduced or avoided. Subsequently, both patterning and trim processes are performed by performing a bake process followed by a developing process. The bake process generates first deprotected regions by increasing a solubility of exposed regions of the photoresist to a developer. The bake process further diffuses an acid from the overcoat layer into perimeter regions of unmodified regions of the photoresist and generates second deprotected regions with increased solubility to the developer. The developing process removes the overcoat layer and the first and second deprotected regions of the photoresist using the developer. Since the first and second deprotected regions are not removed from narrow features, defects due to the trim process may be reduced or avoided. Unmodified regions of the photoresist form one or more trimmed photoresist mandrels.

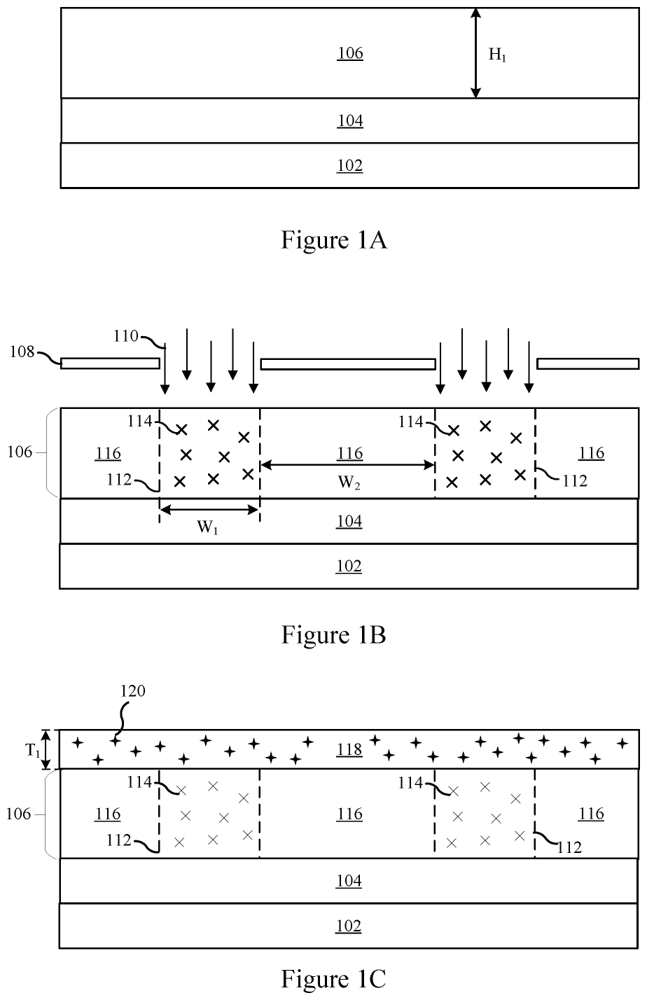

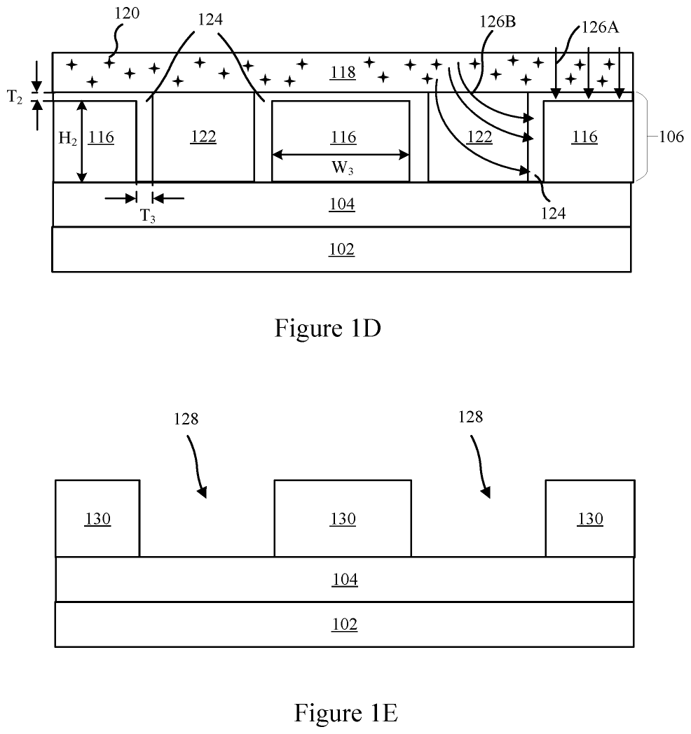

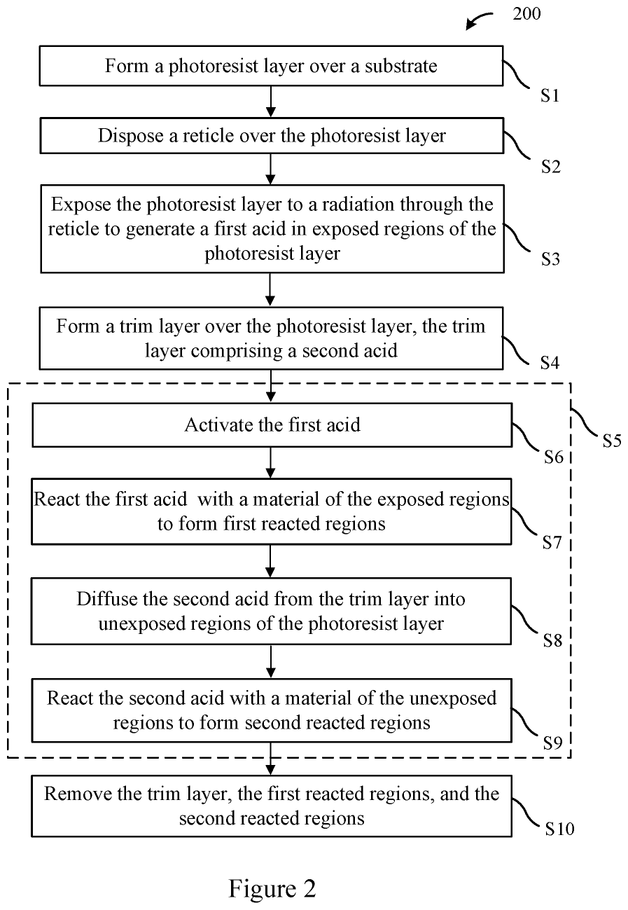

In the following, a process of patterning a photoresist layer 106 is described referring to FIGS. 1A-1E and 2. In particular, FIGS. 1A-1E illustrate cross-sectional views of different stages of a method for patterning the photoresist layer 106 in accordance with various embodiments. FIG. 2 illustrates a process flow diagram of a method 200 for patterning the photoresist layer 106 in accordance with various embodiments.

Referring to FIGS. 1A and 2, in step S1, the photoresist layer 106 is formed over a substrate 102. The substrate 102 may be a part of, or include, a semiconductor device or a semiconductor structure, and may be formed in any suitable manner, including using any suitable combination of wet and/or dry deposition and etch techniques. For example, the semiconductor structure may comprise a substrate 102 in which various device regions are formed. In such embodiments, the substrate 102 may include isolation regions such as shallow trench isolation (STI) regions, diffusion regions, as well as other regions formed therein.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate. In various embodiments, the substrate 102 is patterned or embedded in other components of the semiconductor device or the semiconductor structure.

Referring further to FIG. 1A, in some embodiments, an intermediate layer 104 is formed over the substrate 102 such that the photoresist layer 106 is formed over the intermediate layer 104. The intermediate layer 104 may be a target for pattern transfer in subsequent processing after patterning the photoresist layer 106 from a plurality of mandrels 130 (see FIG. 1E). The intermediate layer 104 may comprise silicon, silicon oxynitride, organic material, non-organic material, amorphous carbon, or the like. The intermediate layer 104 may be selected to have anti-reflective properties such as by using a silicon bottom anti-reflective coating (Si-BARC). The intermediate layer 104 may be a mask layer comprising a hard mask. The hard mask may comprise silicon nitride, silicon dioxide (SiO₂), or titanium nitride. Further, the intermediate layer 104 may be a stacked hard mask comprising, for example, two or more layers of two or more different materials. In embodiments when the hard mask comprises two layers, a first layer of the hard mask may comprise a metal-based layers such as titanium nitride, titanium, tantalum nitride, tantalum, tungsten-based compounds, ruthenium-based compounds, or aluminum-based compounds, and a second layer of the hard mask may comprise a dielectric layer such as silicon dioxide, silicon nitride, silicon oxynitride, silicon carbide, amorphous silicon, or polycrystalline silicon. The intermediate layer 104 may be deposited using suitable deposition processes. Suitable deposition processes may include a spin-on coating process, a chemical vapor deposition (CVD) process, an atomic layer deposition (ALD) process, plasma deposition processes (e.g., a plasma-enhanced CVD (PECVD) process), and/or other layer deposition processes or combinations of processes.

The photoresist layer 106 may be deposited over the intermediate layer 104 in any suitable manner. For example, the photoresist layer 106 may be deposited by spin-coating, spray-coating, dip-coating, or roll-coating. As a particular example, the photoresist layer 106 may be deposited on the substrate 102 using a spin-on deposition technique, which may be also referred to as spin-coating. The photoresist layer 106 may be a planar layer having a thickness H₁. The thickness H₁ may be in a range from 30 nm to 250 nm. The photoresist layer 106 may comprise a multicomponent system including an acid deprotectable terpolymer(s), a photoacid generator and a photodecomposable quencher. The photoresist layer 106 may comprise a positive tone resist or, alternatively, a negative tone resist. In various embodiments, the photoresist layer 106 may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate acid in response to heat or a photoacid generator (PAG) that is configured to generate acid in response to actinic radiation.

With spin-on deposition, a particular material (e.g., the material of the photoresist layer 106) is deposited on the substrate 102 (e.g., on the intermediate layer 104 formed on the substrate 102). The substrate 102 is then rotated (if not already rotating, possibly at a relatively low velocity) at a relatively high velocity so that centrifugal force causes the deposited material to move toward edges of the substrate 102, thereby coating the substrate 102. Excess material is typically spun off the substrate 102. In certain embodiments, the spin-on deposition technique includes dispensing liquid chemicals onto the substrate 102 (e.g., on a top surface of the intermediate layer 104) using a coating module with a liquid delivery system that may dispense one or more types of liquid chemicals. The dispense volume can be in a range from 0.2 ml to 10 ml, for example, in a range from 0.5 ml to 2 ml. The substrate 102 may be secured to a rotating chuck that supports the substrate 102. The rotating speed during liquid dispense can be in a range from 50 rpm to 3000 rpm, for example, in a range from 1000 rpm to 2000 rpm. The system may also include an anneal module that may bake or apply light radiation to the substrate 102 after the chemicals have been dispensed. It should be understood that this example spin-on deposition technique and associated values are provided as examples only. In other embodiments, the photoresist layer 106 may be deposited using a CVD process, a plasma-enhanced CVD process, an ALD process, or other suitable processes.

Referring to FIGS. 1B and 2, in step S2, a reticle 108 is disposed over the photoresist layer 106. The reticle 108 may be used to modulate a dose (or an intensity) of a radiation 110 (e.g., actinic radiation) that is used to expose the photoresist layer 106. In such embodiments, the reticle 108 may comprise regions of different transparency to the radiation 110 (e.g., opaque and transparent regions). The radiation 110 may comprise an ultraviolet (UV) radiation.

Referring further to FIGS. 1B and 2, in step S3, the photoresist layer 106 is subject to an exposure step through the reticle 108. The radiation 110 exposes exposed regions 112 of the photoresist layer while unmodified regions 116 of the photoresist layer 106 are protected by the reticle 108. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology. In some embodiments when 193i lithography is used, the photoresist layer 106 is exposed to a dose of the radiation 110 in a range from 15 mJ/cm² to 50 mJ/cm².

In some embodiments, the radiation 110 generates an acid 114 in the exposed regions 112 of the photoresist layer 106. The acid 114 may be generated from the PAG that is present in the photoresist layer 106 under the influence of the radiation 110. The acid 114 may comprise sulfonic acids such as perfluorobutanesulfonic acid, perfluorooctanesulfonic acid, pentafluorobenzenesulfonic acid, or the like. In some embodiments, the acid 114 may not be in an active state to react with a material of the photoresist layer 106 and alter a solubility of the exposed regions 112 of the photoresist layer 106. In such embodiments, the acid 114 may be activated in a subsequent bake process as described below in a greater detail. In other embodiments, the acid 114 may be in the active state to react with the material of the photoresist layer 106 and alter the solubility of the exposed regions 112 of the photoresist layer 106.

The exposed regions 112 of the photoresist layer 106 may have a width W₁ and unmodified regions 116 of the photoresist layer 106 may have a width W₂. In some embodiments, the width W₁ is same as the width W₂. In other embodiments, the width W₁ is different from the width W₂. The width W₁ may be in a range from 37 nm to 150 nm for 193i lithography. The width W₂ may be in a range from 37 to 150 nm for 193i lithography.

Referring to FIGS. 1C and 2, in step S4, an overcoat layer 118 is deposited over the photoresist layer 106 in any suitable manner. For example, the overcoat layer 118 may be deposited by spin-coating, spray-coating, dip-coating, or roll-coating. As a particular example, the overcoat layer 118 may be deposited on the substrate 102 using a spin-on deposition technique, which may be also referred to as spin-coating. The spin-on deposition technique has been described above with reference to FIG. 1 and the description is not repeated herein. The overcoat layer 118 may be also referred to as a trim layer. The overcoat layer 118 may cover both the exposed regions 112 and the unmodified regions 116 of the photoresist layer 106. The overcoat layer 118 may be a planar layer and may have a thickness T₁ in a range from 10 nm to 100 nm.

The overcoat layer 118 may have a different composition from the photoresist layer 106. In some embodiment, the overcoat layer 118 may be a multicomponent material that, as deposited, includes a first component and a second component. The first component could be, for example, a polymer. The second component could be, for example, a solubility-changing agent, such as an acid 120 (e.g., a free acid). The acid 120 may comprise sulfonic acids such as para-toluenesulfonic acid, perfluorobutanesulfonic acid, mesitylenesulfonic acid, or the like. In some embodiments, the acids 114 and 120 may comprise a same acid. In other embodiments, the acids 114 and 120 may comprise different acids. In some embodiments, a concentration of the acid 120 in the overcoat layer 118 is in a range from 2 wt. % to 20 wt. % relative to the polymer. In some embodiments, a material for the overcoat layer 118 may be chosen such that the overcoat layer 118 could be removed in a subsequent developing process as described below in greater detail.

The second component could be, as another example, an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate acid in response to heat or a photoacid generator (PAG) that is configured to generate acid in response to actinic radiation.

For example, in the case of the overcoat layer 118 including a free acid 120, a solubility-changing agent may be the free acid 120 and subsequent baking of the substrate 102 may cause the free acid 120 to diffuse into perimeter portions of the unmodified regions 116 of the photoresist layer 106 to cause the perimeter portions of the photoresist layer 106 to become soluble in a developer.

As another example, in the case of the overcoat layer 118 including a TAG as an agent-generating ingredient, subsequent baking of the substrate 102 may cause the TAG to generate a solubility-changing agent (e.g., acid), which may be referred to as activating the acid, cause the generated solubility-changing agent to diffuse into perimeter portions of the unmodified regions 116 of the photoresist layer 106 to cause the perimeter portions of the photoresist layer 106 to become soluble in a developer.

As another example, in the case of the overcoat layer 118 including a PAG as an agent-generating ingredient, an exposure step that includes exposing the overcoat layer 118 to a radiation may be performed prior to baking the substrate 102. The exposure step may cause the PAG to generate a solubility-changing agent (e.g., acid), which may be referred to as activating the acid. Baking of the substrate 102 may cause the generated solubility-changing agent to diffuse into perimeter portions of the unmodified regions 116 of the photoresist layer 106 to cause the perimeter portions of the photoresist layer 106 to become soluble in a developer.

Referring to FIGS. 1D and 2, in step S5, a post-exposure bake is performed on the substrate 102. In certain embodiments, the post-exposure bake may be a thermal process that is performed by heating the substrate 102 in a process chamber to a temperature between 50° C. and 250° C., for example, between 60° C. and 140° C. in certain embodiments, in vacuum or under a gas flow. In a particular example, the substrate 102 is baked for a duration in a range from 1 to 3 minutes. The bake conditions of the post-exposure bake may be selected to promote the diffusion of a solubility-changing agent (and possibly generation of the solubility-changing agent from an agent-generating ingredient of the overcoat layer 118, if applicable) and associated change in solubility of perimeter regions of the unmodified regions 116 of the photoresist layer 106 to a target depth. This disclosure contemplates executing the post-exposure bake in any suitable manner.

In some embodiments, the post-exposure bake of step S5 may comprise steps S6 through S9. In step S6, the post-exposure bake activates the acid 114 (see FIG. 1C). In step S7, the acid 114 chemically reacts with a material of the exposed regions 112 of the photoresist layer 106 to form modified regions 122 of the photoresist layer 106. The chemical reaction changes the solubility of the modified regions 122 of the photoresist layer 106 so that the modified regions 122 of the photoresist layer 106 can be removed in a subsequent developing process. In step S8, the acid 120 diffuses from the overcoat layer 118 into the unmodified regions 116 of the photoresist layer 106. In some embodiments, the acid 120 diffuses into perimeter regions of the unmodified regions 116 of the photoresist layer 106 vertically (as indicated by arrows 126A) and laterally (as indicated by arrows 126B) through the modified regions 122 of the photoresist layer 106. In some embodiments, the lateral diffusion rate of the acid 120 is greater than the vertical diffusion rate of the acid 120 due to a high diffusion rate of the acid 120 through the modified regions 122 of the photoresist layer 106. In such embodiments, the acid 120 diffuses into top surfaces of the unmodified regions 116 of the photoresist layer 106 to a first depth and into sidewalls of the unmodified regions 116 of the photoresist layer 106 to a second depth that is greater than the first depth.

In step S9, the acid 120 chemically reacts with a material of the unmodified regions 116 of the photoresist layer 106 to form modified regions 124 of the photoresist layer 106. The chemical reaction changes the solubility of the modified regions 124 of the photoresist layer 106 so that the modified regions 124 of the photoresist layer 106 can be removed in a subsequent developing process. In some embodiments when the acids 114 and 120 comprise a same acid, the modified regions 122 and 124 have a same composition. In other embodiments when the acids 114 and 120 comprise different acids, the modified regions 122 and 124 have different compositions.

Due to the difference in the diffusion rates, the modified regions 124 have a thickness T₂ over top surfaces of the unmodified regions 116 of the photoresist layer 106 and a thickness T₃ along sidewalls of the unmodified regions 116 of the photoresist layer 106, with the thickness T₃ being greater than the thickness T₂. The thickness T₂ may be in a range from 5 nm to 50 nm. The thickness T₃ may be in a range from 5 nm to 50 nm. In some embodiments, the thicknesses T₂ and T₃ may be optimized by altering a composition and a concentration of the acid 120 within the overcoat layer 118 as well as by altering the baking time and/or the temperature of the post-exposure bake.

In certain embodiments, the remaining unmodified regions 116 of the photoresist layer 106 have a reduced height, shown as H₂, relative to the height H₁ (see FIG. 1A) of the photoresist layer 106, and a difference between H₁ and H₂ equals the thickness T₂ of the modified regions 124 of the photoresist layer 106. The height H₂ may be in a range from 20 nm to 200 nm depending on the photoresist material and thickness prior to lithography. For the photoresist layer 106 used in 193i lithography, height H₂ may be in a range from 50 nm to 100 nm. Furthermore, the remaining unmodified regions 116 of the photoresist layer 106 have a reduced width, shown as W₃, relative to the width W₂ of the unmodified regions 116 as shown in FIG. 1B, and a difference between W₂ and W₃ equals twice the thickness T₃ of the modified regions 124 of the photoresist layer 106. The width W₃ may be in a range from 3 nm to 20 nm for a 193i line-space pattern.

Referring to FIGS. 1E and 2, in step S10, a developing step is performed on the substrate 102. The developing step may be performed by a conventional developing method using a developing solution. The developing solution may be also referred to as a developing solvent or a developer. In various embodiments, the developing solution may comprise a metal ion free (MIF) developer, for example, an aqueous solution of tetramethylammonium hydroxide (TMAH). In other embodiments, the developing solution may comprise a metal ion containing developer, for example, an aqueous solution of sodium hydroxide (NaOH) or potassium hydroxide (KOH). In some embodiments, the developing process may comprise soaking the substrate 102 in the developing solution.

In some embodiments, the developing solution removes the overcoat layer 118 (see FIG. 1D), the modified regions 122 and 124 (see FIG. 1D), and forms openings 128 that expose the intermediate layer 104. In an embodiment, the developing solution comprises an aqueous solution of TMAH. Remaining unmodified regions 116 (see FIG. 1D) of the photoresist layer 106 form a plurality of mandrels 130 over the intermediate layer 104. In some embodiments, a pattern of the plurality of mandrels 130 is transferred into the intermediate layer 104. For example, the intermediate layer 104 may be etched by an anisotropic etching process, such as reactive ion etch (RIE), while using the plurality of mandrels 130 as an etch mask. In various embodiments, the transferred pattern may be used to form a contact hole, a via, a metal line, gate line, isolation region, and other features useful in semiconductor fabrication.

Example embodiments of the disclosure are summarized below. Other embodiments can also be understood from the entirety of the specification as well as the claims filed herein.

Example 1. A method includes forming a photoresist layer over a substrate. The method further includes exposing the photoresist layer to a radiation to generate a first acid in exposed regions of the photoresist layer. The method further includes forming a trim layer over the photoresist layer. The trim layer includes a second acid. The method further includes performing a bake process on the substrate having the photoresist layer and the trim layer disposed thereon. Performing the bake process includes reacting the first acid with a material of the exposed regions to form first modified regions, diffusing the second acid from the trim layer into unmodified regions of the photoresist layer, and reacting the second acid with a material of the unmodified regions to form second modified regions. The method further includes and removing the trim layer, the first modified regions, and the second modified regions.

Example 2. The method of example 1, where removing the trim layer, the first modified regions, and the second modified regions includes performing a developing process with a first developer.

Example 3. The method of one of examples 1 and 2, where the first developer includes an aqueous solution of tetramethylammonium hydroxide (TMAH).

Example 4. The method of one of examples 1 to 3, further including, before exposing the photoresist layer to the radiation, disposing a reticle over the photoresist layer.

Example 5. The method of one of examples 1 to 4, where the first acid is different from the second acid.

Example 6. The method of one of examples 1 to 5, where the bake process is performed at a temperature in a range from 50° C. to 250° C. for a duration in a range from 1 min to 3 min.

Example 7. The method of one of examples 1 to 6, where at least a portion of the second acid is diffused into the unmodified regions through the exposed regions.

Example 8. A method includes depositing a photoresist layer over a substrate, disposing a reticle over the photoresist layer, and exposing the photoresist layer to a UV radiation through the reticle to generate a first acid in a first exposed region and a second exposed region of the photoresist layer. A first unmodified region of the photoresist layer is interposed between the first exposed region and the second exposed region. The method further includes depositing a trim layer over the first unmodified region, the first exposed region, and the second exposed region of the photoresist layer. The trim layer includes a second acid. The method further includes performing a bake process on the substrate having the photoresist layer and the trim layer disposed thereon. Performing the bake process includes activating the first acid in the first exposed region and the second exposed region, reacting the first acid with a material of the first exposed region and the second exposed region to form a first modified region and a second modified region, diffusing the second acid from the trim layer into the first unmodified region, and reacting the second acid with a material of the first unmodified region to form a third modified region. The method further includes performing a developing process to remove the trim layer, the first modified region, the second modified region, and the third modified region.

Example 9. The method of example 8, where the third modified region includes a first portion extending along a top of the first unmodified region, the first portion having a first thickness, and a second portion extending along a sidewall of the first unmodified region, the second portion having a second thickness different from the first thickness.

Example 10. The method of one of examples 8 and 9, where the second thickness is greater than the first thickness.

Example 11. The method of one of examples 8 to 10, where a portion of the second acid is diffused into a sidewall of the first unmodified region through the first modified region.

Example 12. The method of one of examples 8 to 11, where the developing process is performed using an aqueous solution of tetramethylammonium hydroxide (TMAH) as a developer.

Example 13. The method of one of examples 8 to 12, where the first acid is same as the second acid.

Example 14. The method of one of examples 8 to 13, where a first diffusion rate of the second acid in the first unmodified region is less than a second diffusion rate of the second acid in the first modified region.

Example 15. A method includes depositing a photoresist layer over a substrate, wherein the photoresist layer has a first solubility to a first developer, disposing a reticle over the photoresist layer, and exposing the photoresist layer to a UV radiation through the reticle to generate a first acid in a first exposed region and a second exposed region of the photoresist layer. A first unmodified region of the photoresist layer is interposed between the first exposed region and the second exposed region. The method further includes depositing a trim layer over the first unmodified region, the first exposed region, and the second exposed region of the photoresist layer, wherein the trim layer has a second solubility to the first developer. The second solubility is greater than the first solubility. The trim layer includes a second acid. The method further includes performing a thermal process on the substrate having the photoresist layer and the trim layer disposed thereon. Performing the thermal process includes activating the first acid in the first exposed region and the second exposed region. Performing the thermal process further includes reacting the first acid with a material of the first exposed region and the second exposed region to form a first modified region and a second modified region. The first modified region and the second modified region have a third solubility to the first developer. The third solubility is greater than the first solubility. Performing the thermal process further includes diffusing the second acid from the trim layer into the first unmodified region, and reacting the second acid with a material of the first unmodified region to form a third modified region. The third modified region has a fourth solubility to the first developer. The fourth solubility is greater than the first solubility. The method further includes soaking the substrate with the photoresist layer and the trim layer disposed thereon in the first developer.

Example 16. The method of example 15, where the first developer includes an aqueous solution of tetramethylammonium hydroxide (TMAH).

Example 17. The method of one of examples 15 and 16, where diffusing the second acid from the trim layer into the first unmodified region includes diffusing a first portion of the second acid into a top surface of the first unmodified region to a first depth, and diffusing a second portion of the second acid into a sidewall of the first unmodified region to a second depth different from the first depth.

Example 18. The method of one of examples 15 to 17, where the photoresist layer is exposed to a dose of the UV radiation a range from 15 mJ/cm² to 50 mJ/cm².

Example 19. The method of one of examples 15 to 18, where the first acid includes a first sulfonic acid.

Example 20. The method of one of examples 15 to 19, where the second acid includes a second sulfonic acid.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming a photoresist layer over a substrate;
exposing the photoresist layer to a radiation to generate a first acid in exposed regions of the photoresist layer;
forming a trim layer over the photoresist layer, wherein the trim layer comprises a second acid;
performing a bake process on the substrate having the photoresist layer and the trim layer disposed thereon, wherein performing the bake process comprises:
reacting the first acid with a material of the exposed regions to form first modified regions;
diffusing the second acid from the trim layer into unmodified regions of the photoresist layer; and
reacting the second acid with a material of the unmodified regions to form second modified regions; and
removing the trim layer, the first modified regions, and the second modified regions.

2. The method of claim 1, wherein removing the trim layer, the first modified regions, and the second modified regions comprises performing a developing process with a first developer.

3. The method of claim 2, wherein the first developer comprises an aqueous solution of tetramethylammonium hydroxide (TMAH).

4. The method of claim 1, further comprising, before exposing the photoresist layer to the radiation, disposing a reticle over the photoresist layer.

5. The method of claim 1, wherein the first acid is different from the second acid.

6. The method of claim 1, wherein the bake process is performed at a temperature in a range from 50° C. to 250° C. for a duration in a range from 1 min to 3 min.

7. The method of claim 1, wherein at least a portion of the second acid is diffused into the unmodified regions through the exposed regions.

8. A method comprising:
depositing a photoresist layer over a substrate;
disposing a reticle over the photoresist layer;
exposing the photoresist layer to a UV radiation through the reticle to generate a first acid in a first exposed region and a second exposed region of the photoresist layer, wherein a first unmodified region of the photoresist layer is interposed between the first exposed region and the second exposed region;
depositing a trim layer over the first unmodified region, the first exposed region, and the second exposed region of the photoresist layer, wherein the trim layer comprises a second acid;
performing a bake process on the substrate having the photoresist layer and the trim layer disposed thereon, wherein performing the bake process comprises:
activating the first acid in the first exposed region and the second exposed region;
reacting the first acid with a material of the first exposed region and the second exposed region to form a first modified region and a second modified region;
diffusing the second acid from the trim layer into the first unmodified region; and
reacting the second acid with a material of the first unmodified region to form a third modified region; and
performing a developing process to remove the trim layer, the first modified region, the second modified region, and the third modified region.

9. The method of claim 8, wherein the third modified region comprises:
a first portion extending along a top of the first unmodified region, the first portion having a first thickness; and
a second portion extending along a sidewall of the first unmodified region, the second portion having a second thickness different from the first thickness.

10. The method of claim 9, wherein the second thickness is greater than the first thickness.

11. The method of claim 8, wherein a portion of the second acid is diffused into a sidewall of the first unmodified region through the first modified region.

12. The method of claim 8, wherein the developing process is performed using an aqueous solution of tetramethylammonium hydroxide (TMAH) as a developer.

13. The method of claim 8, wherein the first acid is same as the second acid.

14. The method of claim 8, wherein a first diffusion rate of the second acid in the first unmodified region is less than a second diffusion rate of the second acid in the first modified region.

15. A method comprising:
depositing a photoresist layer over a substrate, wherein the photoresist layer has a first solubility to a first developer;
disposing a reticle over the photoresist layer;
exposing the photoresist layer to a UV radiation through the reticle to generate a first acid in a first exposed region and a second exposed region of the photoresist layer, wherein a first unmodified region of the photoresist layer is interposed between the first exposed region and the second exposed region;
depositing a trim layer over the first unmodified region, the first exposed region, and the second exposed region of the photoresist layer, wherein the trim layer has a second solubility to the first developer, wherein the second solubility is greater than the first solubility, and wherein the trim layer comprises a second acid;
performing a thermal process on the substrate having the photoresist layer and the trim layer disposed thereon, wherein performing the thermal process comprises:
activating the first acid in the first exposed region and the second exposed region;
reacting the first acid with a material of the first exposed region and the second exposed region to form a first modified region and a second modified region, wherein the first modified region and the second modified region have a third solubility to the first developer, and wherein the third solubility is greater than the first solubility;
diffusing the second acid from the trim layer into the first unmodified region; and
reacting the second acid with a material of the first unmodified region to form a third modified region, wherein the third modified region has a fourth solubility to the first developer, and wherein the fourth solubility is greater than the first solubility; and
soaking the substrate with the photoresist layer and the trim layer disposed thereon in the first developer.

16. The method of claim 15, wherein the first developer comprises an aqueous solution of tetramethylammonium hydroxide (TMAH).

17. The method of claim 15, wherein diffusing the second acid from the trim layer into the first unmodified region comprises:
diffusing a first portion of the second acid into a top surface of the first unmodified region to a first depth; and
diffusing a second portion of the second acid into a sidewall of the first unmodified region to a second depth different from the first depth.

18. The method of claim 15, wherein the photoresist layer is exposed to a dose of the UV radiation a range from 15 mJ/cm² to 50 mJ/cm².

19. The method of claim 15, wherein the first acid comprises a first sulfonic acid.

20. The method of claim 15, wherein the second acid comprises a second sulfonic acid.
